(19) United States
(12) Patent Application Publication
(10) Pub. No.: US 2025/0292945 A1
(43) Pub. Date: Sep. 18, 2025

(54) INTERFACE CIRCUIT EMPLOYING T-COILS IN SERIES

(71) Applicant: QUALCOMM Incorporated, San Diego, CA (US)

(72) Inventors: Hongmei LIAO, San Diego, CA (US); Patrick ISAKANIAN, El Dorado Hills, CA (US); Miao LI, San Diego, CA (US)

(21) Appl. No.: 18/608,696

(22) Filed: Mar. 18, 2024

(51) Int. Cl. H01F 27/28; H01F 27/29; H01L 23/00; H01L 23/522; H01L 23/528

(52) U.S. Cl. CPC H01F 27/2804; H01F 27/292; H01L 23/5227; H01L 23/528; H01L 24/05; H01F 2027/2809; H01L 2224/0401

(57) ABSTRACT

An apparatus has a first spiral coil on a first layer, a second spiral coil adjacent to the first spiral coil on the first layer, a third spiral coil on a second layer that is parallel to the first layer, and a fourth spiral coil adjacent to the third spiral coil on the second layer. The first spiral coil spirals inward in a first direction. The second spiral coil spirals inward in a second direction different from the first direction. The third spiral coil is arranged adjacent the first spiral coil. The fourth spiral coil is arranged adjacent the second spiral coil.

### TECHNICAL FIELD

The technology discussed below relates generally to interface circuits and, more particularly, to an interface circuit that employs multiple T-coils in series.

### INTRODUCTION

Electronic device technologies have seen explosive growth over the past several years. For example, growth of cellular and wireless communication technologies has been fueled by better communications, hardware, larger networks, and more reliable protocols. Wireless service providers are now able to offer their customers an ever-expanding array of features and services, and provide users with unprecedented levels of access to information, resources, and communications. To keep pace with these service enhancements, mobile electronic devices (e.g., cellular phones, tablets, laptops, etc.) have become more powerful and complex than ever. Wireless devices may include a high-speed bus interface for communication of signals between hardware components (e.g., integrated circuits).

Integrated circuit (IC) devices may include a serializer/deserializer (SerDes) interface, a double data rate (DDR) interface, or some other type of high-speed interface to transmit and receive via a communication link. Performance, accuracy and/or reliability of data communication interfaces may depend on the driver circuits and the receiver circuits that are expected to accommodate high transmission speed, and other factors that can impact the operation of high-speed data links. Therefore, there is an ongoing need for improvements that provide reliable transmission of clock, data, and control signals over high-speed data links.

### BRIEF SUMMARY OF SOME EXAMPLES

The following presents a summary of one or more aspects of the present disclosure, in order to provide a basic understanding of such aspects. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in a form as a prelude to the more detailed description that is presented later.

In various aspects of the disclosure, an apparatus includes a first spiral coil on a first layer, a second spiral coil adjacent to the first spiral coil on the first layer, a third spiral coil on a second layer that is parallel to the first layer, and a fourth spiral coil adjacent to the third spiral coil on the second layer. The first spiral coil includes a first end and a second end, with the first end being coupled to a first interconnect, the second end being coupled to a first terminal, and the first spiral coil spiraling inward from the second end to the first end in a first direction. The second spiral coil includes a third end and a fourth end, with the third end being coupled to a second interconnect, the fourth end being coupled to the first terminal, and the second spiral coil spiraling inward from the fourth end to the third end in a second direction different from the first direction. The third spiral coil includes a fifth end and a sixth end, with the fifth end being coupled to the first interconnect, the sixth end being coupled to a second terminal, and the third spiral coil being arranged adjacent the first spiral coil. The fourth spiral coil includes a seventh end and an eighth end, with the seventh end being coupled to the second interconnect, the eighth end being coupled to a third terminal, and the fourth spiral coil being arranged adjacent the second spiral coil.

In various aspects of the disclosure, an integrated circuit includes a first metal layer defining a first spiral coil, a second spiral coil, and a first terminal. The apparatus also includes a second metal layer defining a third spiral coil, a fourth spiral coil, a second terminal, and a third terminal. The apparatus further includes a first inter-layer interconnect between the first metal layer and the second metal layer, as well as a second inter-layer interconnect between the first metal layer and the second metal layer. A first end of the first spiral coil is coupled to the first inter-layer interconnect, and a second end of the first spiral coil is coupled to the first terminal, with the first spiral coil spiraling inward from the second end to the first end in a clockwise direction. A third end of the second spiral coil is coupled to the second inter-layer interconnect, and a fourth end of the second spiral coil is coupled to the first terminal, with the second spiral coil spiraling inward from the fourth end to the third end in a counter-clockwise direction. A fifth end of the third spiral coil is coupled to the first inter-layer interconnect, and a sixth end of the third spiral coil is coupled to the second terminal, with the third spiral coil being arranged adjacent the first spiral coil. A seventh end of the fourth spiral coil is coupled to the second inter-layer interconnect, and an eighth end of the fourth spiral coil is coupled to the third terminal, with the fourth spiral coil being arranged adjacent the second spiral coil.

In various aspects of the disclosure, an apparatus includes a first T-coil and a second T-coil. The first T-coil includes a first coil coupled to a second coil at a first node. The first T-coil also includes a first electrical component coupled to the first node. The second T-coil includes a third coil coupled to a fourth coil at a second node. The second T-coil also includes a second electrical component coupled to the second node. The second T-coil is coupled to the first T-coil at a third node. The apparatus also includes a third electrical component coupled to the third node.

These and other aspects of the disclosure will become more fully understood upon a review of the detailed description which follows. Other aspects, features, and examples of the present disclosure will become apparent to those of ordinary skill in the art, upon reviewing the following description of specific, example aspects of the present disclosure in conjunction with the accompanying figures. While features of the present disclosure may be discussed relative to certain examples and figures below, all examples of the present disclosure can include one or more of the advantageous features discussed herein. In other words, while one or more examples may be discussed as having certain advantageous features, one or more of such features may also be used in accordance with the various examples of the disclosure discussed herein. In similar fashion, while example aspects may be discussed below as device, system, or method examples it should be understood that such example aspects can be implemented in various devices, systems, and methods.

### BRIEF DESCRIPTION OF THE DRAWINGS

FIG. 1 illustrates an example of a system-on-a-chip (SOC) that may be adapted in accordance with certain aspects of the disclosure.

FIG. 2 illustrates an example of a system that employs a multi-channel data communication link in accordance with certain aspects of the disclosure.

FIG. 3 illustrates certain features of an input/output circuit in a high-speed memory interface in accordance with certain aspects of the disclosure.

FIG. 4 illustrates an example of a T-coil circuit.

FIG. 5 illustrates an example layout of the T-coil circuit of FIG. 4.

FIG. 6 illustrates an example of a T-coil circuit that includes two T-coils in series in accordance with certain aspects of the disclosure.

FIG. 7 illustrates an example layout of the T-coil circuit of FIG. 6 in accordance with certain aspects of the disclosure.

FIG. 8 illustrates example layers of the layout of FIG. 7 in accordance with certain aspects of the disclosure.

FIG. 9 contrasts the layout of FIG. 7 with the layout of FIG. 5 for a multi-lane scenario in accordance with certain aspects of the disclosure.

FIG. 10 illustrates example layouts of the T-coil circuit of FIG. 6 or FIG. 11 for multi-lane scenarios in accordance with certain aspects of the disclosure.

FIG. 11 illustrates another example of a T-coil circuit that includes two T-coils in series in accordance with certain aspects of the disclosure.

FIG. 12 illustrates an example of an apparatus that may employ T-coils in accordance with certain aspects of the disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

While aspects and examples are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip examples and other non-module-component based devices (e.g., end-user devices, vehicles, communication devices, computing devices, industrial equipment, retail/purchasing devices, medical devices, artificial intelligence-enabled (AI-enabled) devices, etc.). While some examples may or may not be specifically directed to use cases or applications, a wide assortment of applicability of described innovations may occur. Implementations may range a spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described examples. For example, transmission and reception of wireless signals necessarily includes a number of components for analog and digital purposes (e.g., hardware components including antenna, radio frequency (RF) chains, power amplifiers, modulators, buffer, processor(s), interleaver, adders/summers, etc.). It is intended that innovations described herein may be practiced in a wide variety of devices, chip-level components, systems, distributed arrangements, disaggregated arrangements (e.g., base station and/or UE), end-user devices, etc., of varying sizes, shapes, and constitution.

The terms “computing device” and “mobile device” are used interchangeably herein to refer to any one or all of servers, personal computers, smartphones, cellular telephones, tablet computers, laptop computers, notebooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., read only memory (ROM), random access memory (RAM), flash, etc.), and resources (e.g., timers, voltage regulators, oscillators, etc.), any or all of which may be included in one or more cores.

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

ICs typically provide multiple voltage domains for power saving purposes. For example, higher voltage domains provide power at higher voltage levels than lower voltage domains. Higher voltage domains are sometimes needed for interfacing with external devices, while core logic circuits can generally operate at the lower voltage levels available in lower voltage domains. For the purposes of this disclosure, a thick-oxide transistor may refer to a transistor that has a gate oxide thickness sufficient to enable the transistor to withstand and operate at the higher voltage levels in higher voltage domains and a thin-oxide transistor may refer to a transistor that has a gate oxide thickness that is insufficient to avoid electrical overstress when the transistor spans a higher voltage level in the higher voltage domains. In certain examples disclosed herein, a thin-oxide transistor may be rated for voltages up to 0.6 volts and a thick-oxide transistor may be rated for voltages greater than 0.6 volts and thick-oxide transistors may be used in a higher a high-voltage domain that provides power at 1.2 volts.

Certain circuits are illustrated in this disclosure as being implemented using combinations of P-type metal-oxide-semiconductor (PMOS) transistors and N-type metal-oxide-semiconductor (NMOS) transistors. These circuits are provided by way of example only, and it is contemplated that the concepts disclosed herein can be implemented in circuits that use different combinations of NMOS and PMOS transistors. Circuits that include NMOS and PMOS transistors are typically coupled to the rails of a power supply. The power supply provides a current that flows from a higher voltage rail to a lower voltage rail. A rail may include some combination of conductors, wires, connectors and other types of interconnect. For the purposes of this description, the higher voltage rail may be referenced as “VDD” or “VDD” and the lower voltage rail may be referred to as Ground. In some implementations, power may be provided to certain circuits through more than two rails.

Advancements in process technologies tend to reduce transistor gate length and other feature sizes with IC devices. Reductions in gate length and feature sizes can increase the susceptibility of IC devices to electrostatic discharge (ESD) events. IC devices often include ESD protection circuits that can protect interface circuits during different types of ESD events. IC devices may be tested to ensure that they meet minimum industry standards regarding ESD protection. IC device qualification processes may include testing the susceptibility of the IC device to ESD events based on a human-body model (HBM) or based on a charged-device model (CDM) characterization of ESD events. Some ESD protection circuits are based on or evaluated using an HBM or a CDM. The HBM is intended to characterize the susceptibility of devices to damage from ESD events of ±1 k Volt resulting from human touching of an electronic device. The CDM is intended to characterize the susceptibility of devices to damage from ESD events of ±250 Volts that relate to sudden discharges of energy accumulated in an IC chip or package through direct contact charging or field-induced charging.

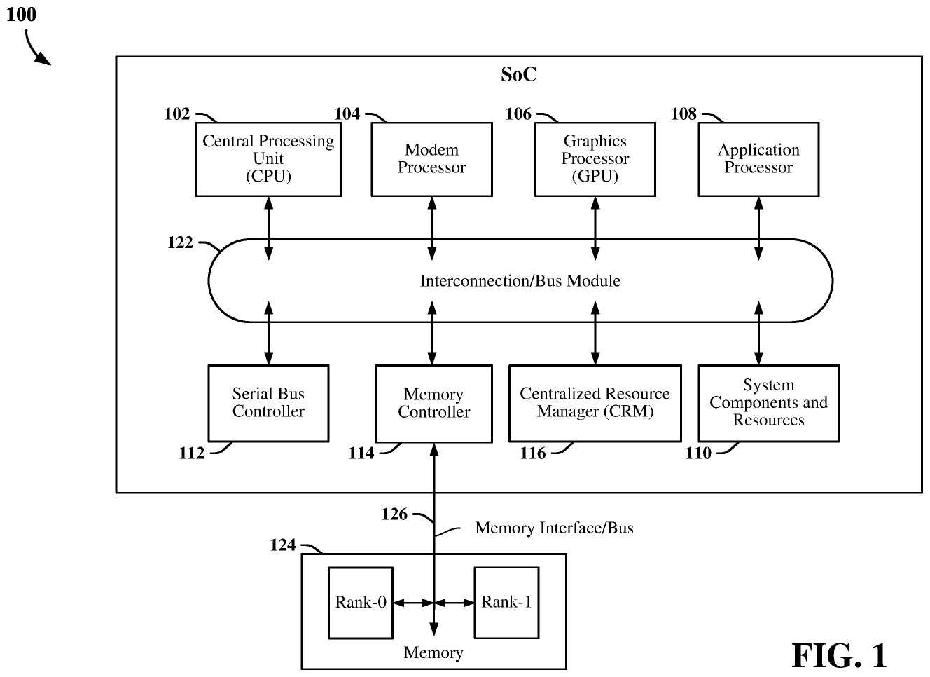

FIG. 1 illustrates examples of components and interconnections in a system-on-chip (SoC) 100, including a memory interface/bus 126, that may be suitable for implementing certain aspects of the present disclosure. The SoC 100 may include a number of heterogeneous processors, such as a central processing unit (CPU) 102, a modem processor 104, a graphics processor 106, and an application processor 108. Each processor 102, 104, 106, 108, may include one or more cores, and each processor/core may perform operations independent of the other processors/cores. The processors 102, 104, 106, 108 may be organized in close proximity to one another (e.g., on a single substrate, die, integrated chip, etc.) so that the processors may operate at a much higher frequency/clock rate than would be possible if the signals were to travel off-chip. The proximity of the cores may also allow for the sharing of on-chip memory and resources (e.g., voltage rails), as well as for more coordinated cooperation between cores.

The SoC 100 may include interface circuits that support inter-processor communication and/or communication between one or more of the processors 102, 104, 106, 108, memory, wireless modems, and other peripherals. Many of these interface circuits are based on serializer/deserializer (SerDes) circuits that enable transmission and reception of data over a communication link. In some examples, a SerDes transmitter may convert parallel data to serial data for transmission via a serial link, while a SerDes receiver may convert serial data received via the serial link to parallel data. SerDes circuits may be used to support high-speed communication and/or low-speed communication.

The SoC 100 may include system components and resources 110 for managing sensor data, analog-to-digital conversions, and/or wireless data transmissions, and for performing other specialized operations (e.g., decoding high-definition video, video processing, etc.). System components and resources 110 may also include components such as voltage regulators, oscillators, phase-locked loops (PLLs), peripheral bridges, data controllers, system controllers, access ports, timers, and/or other similar components used to support the processors and software clients running on the computing device. The system components and resources 110 may also include circuitry for interfacing with peripheral devices, such as cameras, electronic displays, wireless communication devices, external memory chips, etc.

The SoC 100 may further include a Universal Serial Bus (USB) or other serial bus controller 112, one or more memory controllers 114, and a centralized resource manager (CRM) 116. The SoC 100 may also include an input/output module (not illustrated) for communicating with resources external to the SoC, each of which may be shared by two or more of the internal SoC components.

The processors 102, 104, 106, 108 may be interconnected to the USB controller 112, the memory controller 114, system components and resources 110, CRM 116, and/or other system components via an interconnection/bus module 122, which may include an array of reconfigurable logic gates and/or implement a bus architecture. Communications may also be provided by advanced interconnects, such as high-performance networks on chip.

The interconnection/bus module 122 may include or provide a bus mastering system configured to grant SoC components (e.g., processors, peripherals, etc.) exclusive control of the bus (e.g., to transfer data in burst mode, block transfer mode, etc.) for a set duration, number of operations, number of bytes, etc. In some cases, the interconnection/bus module 122 may implement an arbitration scheme to prevent multiple master components from attempting to drive the bus simultaneously.

The memory controller 114 may be a specialized hardware module configured to manage the flow of data to and from a memory 124 via the memory interface/bus 126. In some examples, the memory controller 114 includes one or more processors configured to perform read and write operations with the memory 124. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure.

Memory technologies described herein may be suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

Certain aspects of the disclosure are applicable to data communication interfaces that include SerDes circuits. For example, SerDes-based data communication interfaces may be used in communication links operated in accordance with Peripheral Component Interconnect Express (PCIe) or USB protocols, and in Advanced High-Performance Bus (AHB) protocols defined by Advanced Microcontroller Bus Architecture (AMBA) specifications. SerDes-based data communication interface may be used to provide an interface between core circuits and Synchronous Dynamic Random Access Memory (SDRAM) devices, including Low-Power double data rate SDRAM (LPDDR SDRAM) that can be configured for high-speed and low-power modes of operation.

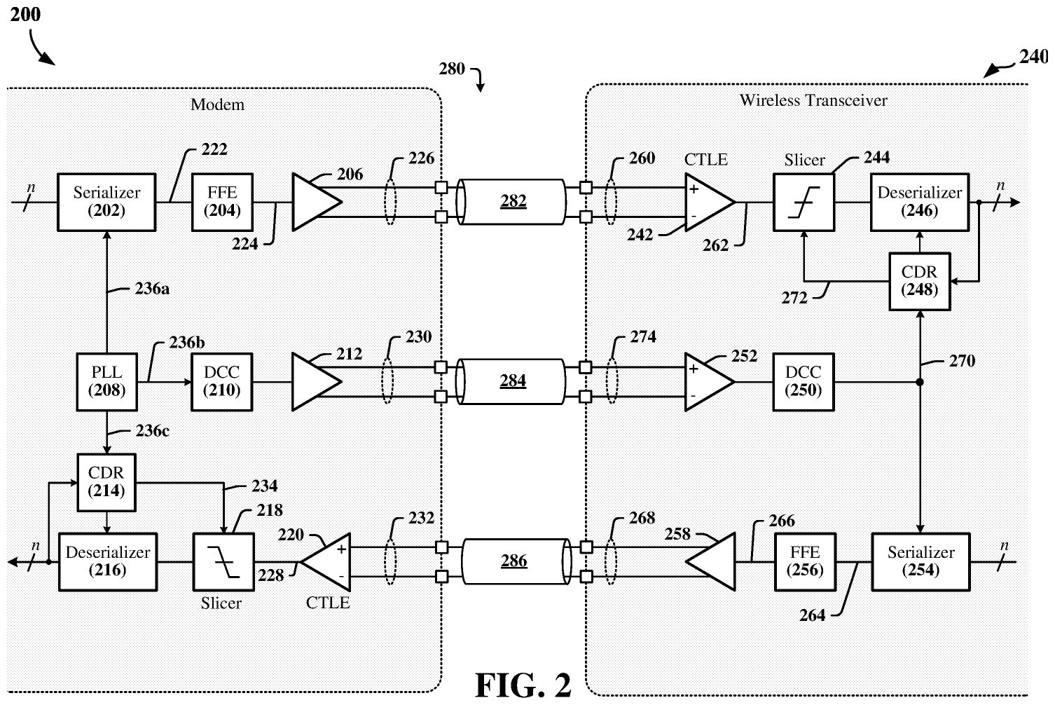

FIG. 2 illustrates an example of a system that employs a SerDes-based multi-channel data communication link 280 to couple a modem 200 with a wireless transceiver 240. The data communication link 280 includes data channels 282 and 286 and a clock channel 284 that provide a transmission medium through which signals propagate between devices. In the illustrated example, a modem 200 transmits data in a first signal over a first data channel 282 to a wireless transceiver 240 and receives data in a second signal transmitted over a second data channel 286. Data signals are transmitted over the data channels 282 and 286 in accordance with timing information provided by a bus clock signal 230 transmitted over the clock channel 284.

The modem 200 may include a serializer 202 configured to convert n-bit parallel data elements, bytes or words into a serial data stream for transmission in a serialized data signal 222. The serialized data signal 222 may be preconditioned by a pre-equalizing circuit, such as the illustrated digital feed-forward equalizer (the FFE 204), in order to combat or compensate for signal distortions attributable to inter-symbol interference (ISI), reflection and other effects that can be expected to limit bandwidth in the first data channel 282. A preconditioned data signal 224 output by the FFE 204 is provided to a driver circuit 206 that is configured generate and transmit a differential transmit data signal 226 over the first data channel 282. For the purposes of this disclosure, a differential signal includes two complementary signals that are phase-shifted by 180° with respect to one another.

The wireless transceiver 240 can be configured to process a data signal 260 received over the first data channel 282. The data signal 260 may be provided to a differential receiver 242, which may include or cooperate with an equalizing circuit. In one example, continuous time linear equalization (CTLE) may be used to compensate for certain losses experienced in the first data channel 282. The first data channel 282 may be characterized in some respects as a low-pass filter. In the illustrated example, the differential receiver 242 outputs an equalized data signal 262 that is sampled by a slicer 244. The slicer 244 may be implemented using a D-flipflop or the like and may be configured to capture signaling state of the equalized data signal 262 under the control of edges in a sampling clock signal 272 generated by a clock and data recovery (CDR) circuit 248. The output of the slicer 244 may be provided to a deserializer 246 that is clocked in accordance with one or more clock signals provided by the CDR circuit 248. The CDR circuit 248 may be configured to delay or phase shift a receiver clock signal 270 to ensure that edges in the sampling clock signal 272 are timed to optimize sampling reliability.

In the illustrated wireless transceiver 240, the receiver clock signal 270 is derived from a received bus clock signal 274 from the clock channel 284. A differential receiver 252 coupled to the clock channel 284 may be configured to equalize the received bus clock signal 274, and a duty cycle correction circuit 250 may be used to adjust the duty cycle of the receiver clock signal 270. The receiver clock signal 270 is provided to a serializer 254 that is configured to convert n-bit parallel data elements, bytes or words into a serial data stream for transmission in a serialized data signal 264. The serialized data signal 264 may be preconditioned by a pre-equalizing circuit, such as the illustrated FFE 256, in order to combat or compensate for signal distortions attributable to ISI, reflection and other effects that can be expected to limit bandwidth in the second data channel 286. A preconditioned data signal 266 output by the FFE 256 is provided to a driver circuit 258 that is configured generate and transmit a differential transmit data signal 268 over the second data channel 286.

The illustrated modem 200 can be configured to process a data signal 232 received over the second data channel 286. The data signal 232 may be provided to a differential receiver 220, which may include or cooperate with an equalizing circuit. In one example, CTLE may be used to compensate for certain losses experienced in the second data channel 286. The second data channel 286 may be characterized in some respects as a low-pass filter. In the illustrated example, the differential receiver 220 outputs an equalized data signal 228 that is sampled by a slicer 218. The slicer 218 may be implemented using a D-flipflop or the like and may be configured to capture signaling state of the equalized data signal 228 under the control of edges in a sampling clock signal 234 generated by a CDR circuit 214. The output of the slicer 218 may be provided to a deserializer 216 that is clocked in accordance with one or more clock signals provided by the CDR circuit 214. The CDR circuit 214 may be configured to delay or phase shift a transmitter clock signal to ensure that edges in the sampling clock signal 234 are timed to optimize sampling reliability.

A clock generation circuit, including the illustrated phase locked loop 208, may generate multiple clock signals 236a, 236b, 236c used by the modem 200. One or more of the clock signals 236a, 236b, 236c may be a divided version of a base clock signal generated by the PLL 208. One or more of the clock signals 236a, 236b, 236c may be phase shifted with respect to the base clock signal. In one example, the serializer 202 may produce the serialized data signal 222 using timing provided by a first clock signal 236a. In another example, the bus clock signal 230 transmitted over the clock channel 284 may be derived from a second clock signal 236b. In some instances, a duty cycle correction circuit 210 may be used to adjust the duty cycle of the second clock signal 236b and to provide an input to a driver circuit 212 that is configured drive the clock channel 284. In another example, the CDR circuit 248 may generate the sampling clock signal 234 from a third clock signal 236c.

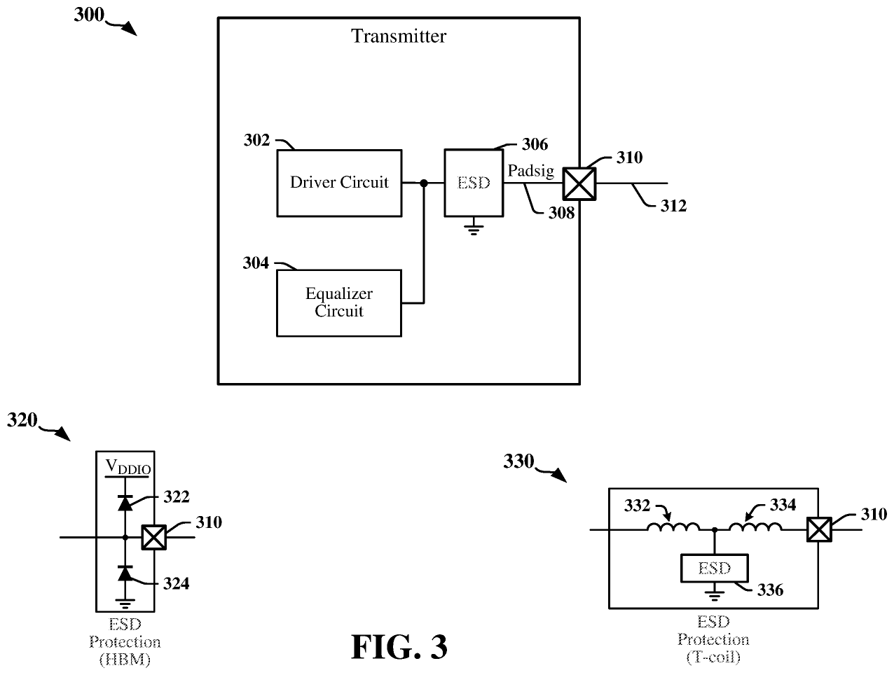

Certain features of an input/output (I/O) circuit 300 are illustrated in FIG. 3. The I/O circuit 300 may be implemented in a DDR circuit, a SerDes circuit, or some other circuit that includes a physical interface (PHY) I/O circuit.

The I/O circuit 300 may be coupled to an I/O terminal 310. The I/O terminal 310 may be coupled to a line 312 of a high-speed bus (a serial bus or a parallel bus) that interconnects two chips, such as, for example, a memory controller and one or more memory devices, etc. An ESD protection circuit 306 may be coupled to the I/O terminal 310. For the purposes of this description, the I/O terminal 310 may correspond to a bonding pad in an IC device or SoC that facilitates bonding or contacting with a connecting wire or other interconnect.

The I/O circuit 300 includes a driver circuit 302 and an equalizer circuit 304 (e.g., for a serial bus or for a lane of a parallel bus). The bandwidth of the I/O circuit 300 is limited by certain alternating current (AC) characteristics of the driver circuit 302, the equalizer circuit 304, the ESD protection circuit 306 and the line 312 coupled to the I/O terminal 310, which can contribute to the I/O capacitance (C_{IO}) measured at the I/O terminal 310. C_{IO} is typically a critical parameter and can limit AC performance at higher frequencies. The equalizer circuit 304 may be configured to offset certain effects of C_{IO} and other parameters that may introduce distortion and non-linear response of the I/O circuit 300 and line 312. In some examples, the equalizer circuit 304 may be configured to provide or approximate pre-emphasis in order to mitigate for channel loss and linear inter-symbol interference (ISI). ISI can distort signals when a pulse or an edge transmitted in a time interval (i.e., a unit interval or UI) is affected by a pulse or an edge transmitted in a preceding UI due to non-linear frequency response of the line 312, for example. The equalizer circuit 304 may be provided to enable the I/O circuit 300 to operate at, or switch between standards-defined frequencies for LPDDR SDRAM of 6.4 GHZ and 4.8 GHZ, for example.

FIG. 3 includes an example of an ESD protection circuit 320 (e.g., corresponding to the ESD protection circuit 306). The ESD protection circuit 320 may be HBM-qualified or CDM-qualified in some examples. The ESD protection circuit 320 includes two diodes 322, 324 that are reverse biased unless a current surge causes a voltage at the I/O terminal 310 to exceed the nominal or rated voltage of the power supply provided to the I/O circuit 300.

FIG. 3 includes a second example of an ESD protection circuit 330. The ESD protection circuit 330 has a single T-coil that may include an ESD discharge circuit 336 that provides a discharge path to a power rail when a voltage applied to the I/O terminal 310 exceeds the nominal or rated voltage of the power supply. In one example, the one or more diodes (not shown) in the ESD discharge circuit 336 may be reverse biased unless an overvoltage condition occurs responsive to a current surge. The ESD discharge circuit 336 is coupled between two series-connected inductors 332, 334 that couple one or more driver circuits to the I/O terminal 310.

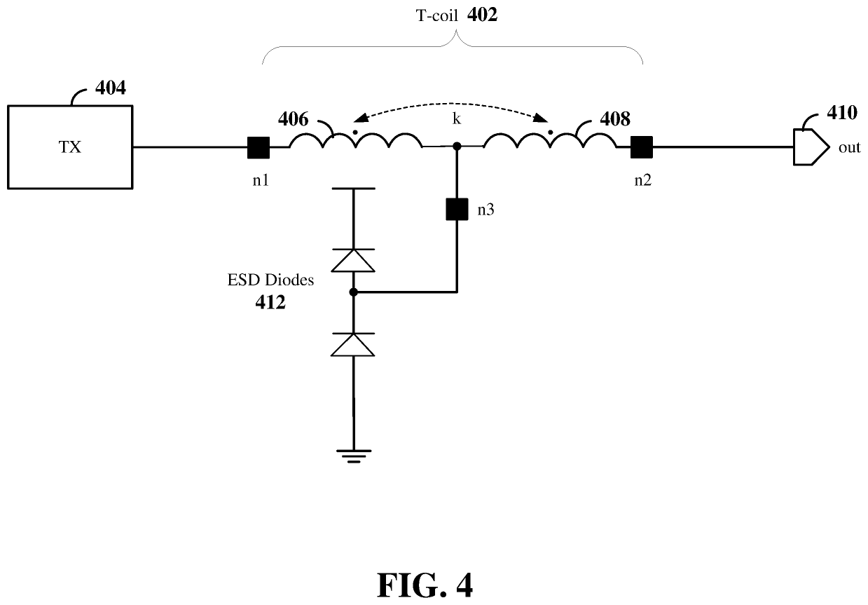

The T-coil may be used to compensate for capacitance of an ESD circuit (e.g., the ESD discharge circuit 336), and therefore extend the bandwidth of the signal path. Thus, T-coils may be used for high-speed serial communication data interfaces and links between chips to extend the bandwidth for transmitters and/or receivers. FIG. 4 illustrates an example of a T-coil 402 implemented with a transmitter 404 (e.g., a driver circuit as discussed above).

The T-coil 402 includes a first coil 406 (e.g., an inductance clement) and a second coil 408 connected in series. The first coil 406 and the second coil 408 are placed adjacent to each other whereby a change in a current in one coil induces an electromagnetic field in the other coil (e.g., as characterized by a mutual inductance factor k). The T-coil 402 includes (or is coupled to) a first node n1, a second node n2, and a third node n3 as shown in FIG. 4. The nodes may be referred to as terminals, pins, pads, or some other terminology in various contexts. The first node n1 is coupled to output of the transmitter 404, the second node n2 is coupled to an output pad 410, and the third node n3 is coupled to a pair of ESD diodes 412. Thus, a signal from the transmitter 404 passes through the T-coil 402 to the output pad 410 (e.g., for transmission to an off-chip component).

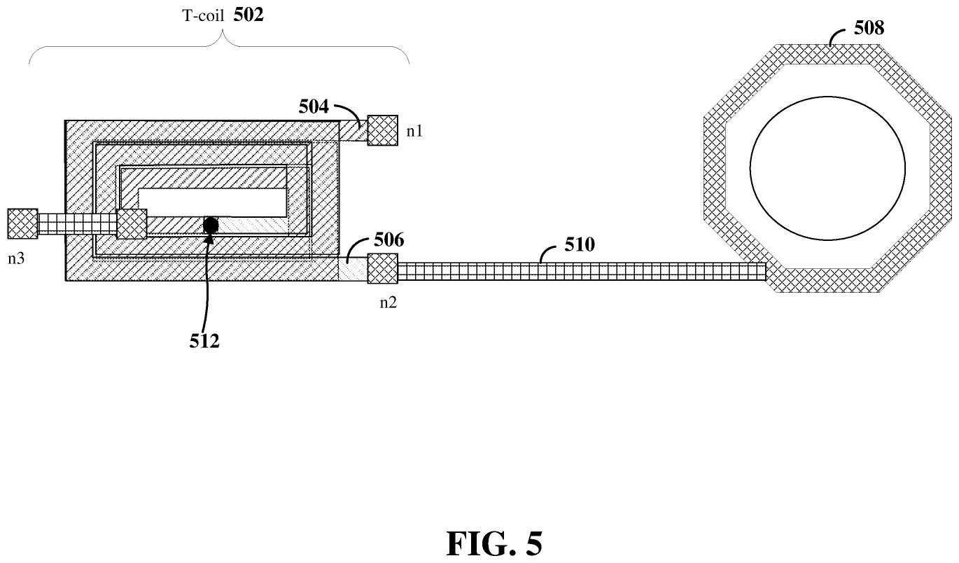

FIG. 5 illustrates a top view of an example layout of a T-coil 502 corresponding to the T-coil 402 of FIG. 4. In this example, the first coil 504 (e.g., the coil 406 of FIG. 4) is routed on a first IC layer and the second coil 506 (e.g., the coil 408 of FIG. 4) is routed on a second IC layer. For purposes of illustration, the first coil 504 and the second coil 506 are shown in a see-through manner to better indicate the layouts of the coils relative to one other.

One end of the first coil 504 is coupled to a first node n1 and the other end of the first coil 504 is coupled to an inter-layer interconnect 512 (e.g., a so-called via) at the first IC layer. One end of the second coil 506 is coupled to a second node n2 and the other end of the second coil 506 is coupled to the inter-layer interconnect 512 at the second IC layer. The third node n3 is coupled to the T-coil 502 near the inter-layer interconnect 512.

The second node n2 is coupled to an output pad 508 via a signal trace 510. Thus, as in FIG. 4, a signal from a transmitter (not shown in FIG. 5) flows from the first node n1 through the T-coil 502, out the second node n2, and to the output pad 508 (e.g., for transmission to an off-chip component).

As indicated, the T-coil design of FIGS. 4 and 5 has two nodes within a close distance to one another where one node (node n2) is connected to the output pad and the other node (node n1) is connected to the output of a transmitter (e.g., the transmitter 404). This design takes up relatively expensive silicon area when the T-coil 502 and the output pad 508 are created as a separate elements (cells), with each element (cell) occupying its own space.

Moreover, the long connection (signal trace 510) between the T-coil 502 and the output pad 508 increases the parasitic capacitance of the circuit. Such parasitics may degrade the bandwidth and performance of the circuit, particularly at higher data rates (e.g., 8 gigabits per second and above).

Furthermore, high-speed data communication and link protocols often require multiple serial interface lanes, e.g., 16 lanes, which requires multiple T-coils and I/O pads. However, the long connection (signal trace 510) between the T-coil and the output pad 508 in the design of FIG. 5 makes it relatively difficult to match different I/O lanes with corresponding T-coils and output pads due to area limitations and limitations in the output pad arrangements. This layout issue further degrades the bandwidth and performance of the circuit.

The disclosure relates in some aspects to a T-coil design that employs multiple (e.g., 2, 3, 4 or more) T-coils. In some aspects, the T-coils may serve two functions. First, the T-coils may serve as a long metal signal wire that connects a signal coming from a circuit on chip to an I/O pad (e.g., a bump), or vice versa. Second, the T-coils may extend the bandwidth of the circuit beyond what is achievable using only a single T-coil (e.g., since the multiple T-coil design may have a higher inductance than the single T-coil design).

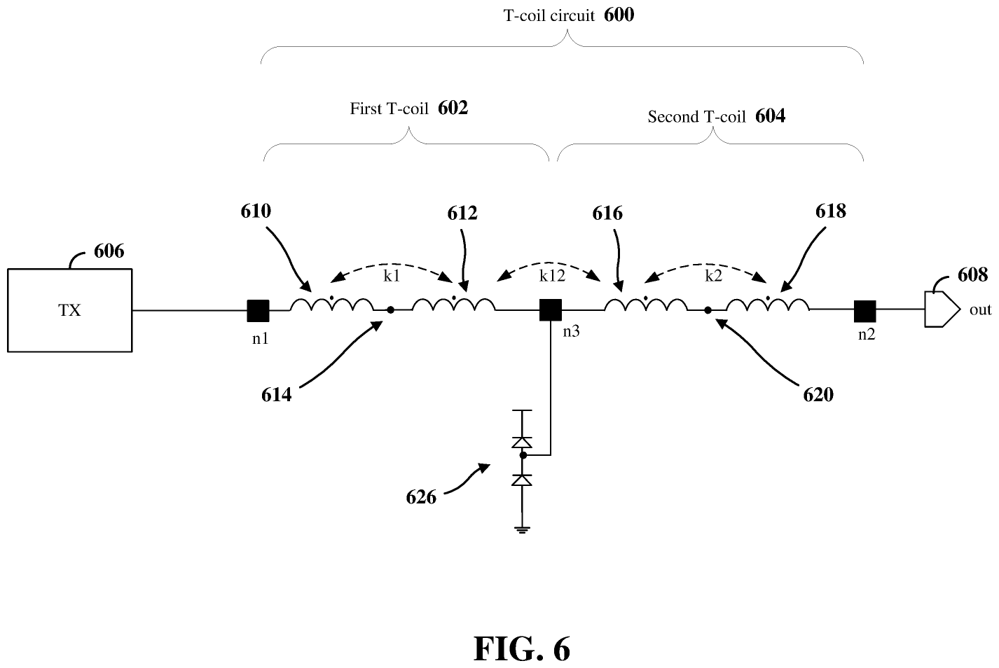

FIG. 6 illustrates an example of a T-coil circuit 600 that includes a first T-coil 602 and a second T-coil 604 in accordance with certain aspects of the disclosure. In this examples, the T-coil circuit 600 couples the output of a transmitter 606 to an output pad 608.

The first T-coil 602 includes a first coil 610 (e.g., a first inductance element) and a second coil 612 (e.g., a second inductance element) connected in series at a first intermediate node 614. The first coil 610 and the second coil 612 are placed adjacent to each other whereby a change in a current in one coil induces an electromagnetic field in the other coil (e.g., as characterized by a mutual inductance factor k1).

The second T-coil 604 includes a third coil 616 (e.g., a third inductance element) and a fourth coil 618 (e.g., a fourth inductance element) connected in series at a second intermediate node 620. The third coil 616 and the fourth coil 618 are placed adjacent to each other whereby a change in a current in one coil induces an electromagnetic field in the other coil (e.g., as characterized by a mutual inductance factor k2).

The T-coil circuit 600 includes (or is coupled to) a first node n1, a second node n2, and a third node n3 as shown in FIG. 6. The nodes may be referred to as terminals, pins, pads, or some other terminology in various contexts. The first node n1 is coupled to output of the transmitter 606, the second node n2 is coupled to an output pad 608, and the third node n3 is coupled to a pair of ESD diodes 626. Thus, a signal from the transmitter 606 passes through the T-coil circuit 600 to the output pad 608 (e.g., for transmission to an off-chip component).

In some examples, the first T-coil 602 and the second T-coil 604 may be distributed T-coils. For example, the first T-coil 602 and the second T-coil 604 may be separated from one another so that the mutual inductance between the first T-coil 602 and the second T-coil 604 (e.g., as characterized by a mutual inductance factor k12) meets a design criteria. As discussed in more detail below, in some examples, this may involve placing the T-coils next to each other on a common layer or layers (e.g., as opposed to stacking the T-coils one above the other on different layers). In some examples, the mutual inductance factor k12 is less than 0.6.

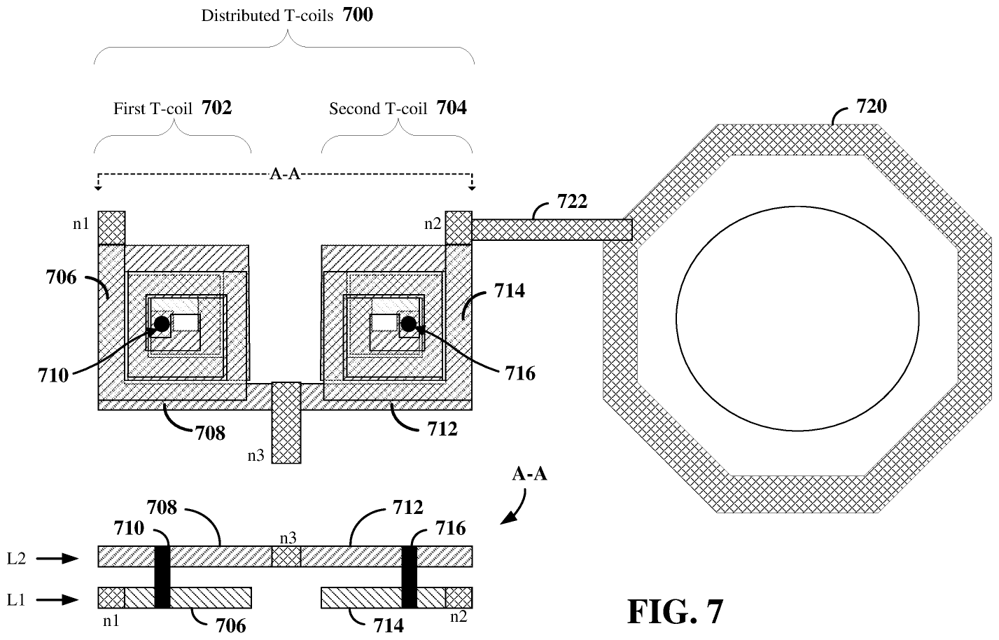

FIG. 7 illustrates a top view of an example layout of distributed T-coils 700 corresponding to the T-coil circuit 600 of FIG. 6 in accordance with certain aspects of the disclosure. The distributed T-coils 700 include a first T-coil 702 (e.g., corresponding to the first T-coil 602 of FIG. 6) and a second T-coil 704 (e.g., corresponding to the second T-coil 604 of FIG. 6). For purposes of illustration, each of the first T-coil 702 and the second T-coil 704 is shown in a see-through manner to better indicate the layouts of the corresponding coils relative to one other.

The first T-coil 702 includes a first coil 706 (e.g., corresponding to the first coil 610 of FIG. 6) and a second coil 708 (e.g., corresponding to the second coil 612 of FIG. 6). In this example, the first coil 706 is routed on a first IC layer and the second coil 708 is routed on a second IC layer. One end of the first coil 706 is coupled to a first node n1 and the other end of the first coil 504 is coupled to an inter-layer interconnect 710 (e.g., a so-called via) at the first IC layer. One end of the second coil 708 is coupled to a third node n3 and the other end of the second coil 708 is coupled to the inter-layer interconnect 710 at the second IC layer.

The second T-coil 704 includes a third coil 712 (e.g., corresponding to the third coil 616 of FIG. 6) and a fourth coil 714 (e.g., corresponding to the fourth coil 618 of FIG. 6). In this example, the third coil 712 is routed on the second IC layer and the fourth coil 714 is routed on the first IC layer. One end of the third coil 712 is coupled to the third node n3 and the other end of the third coil 712 is coupled to a second inter-layer interconnect 716 at the second IC layer. One end of the fourth coil 714 is coupled to a second node n2 and the other end of the fourth coil 714 is coupled to the second inter-layer interconnect 716 at the first IC layer.

The partial side view A-A further illustrates that the first coil 706 is implemented in the first layer L1 (e.g., a first metal layer of an IC), the second coil 708 is implemented in the second layer L2 (e.g., a second metal layer of the IC), the third coil 712 is implemented in the second layer L2, and the fourth coil 714 is implemented in the first layer L1. Here, it may be seen that that the second coil 708 is adjacent the first coil 706 in the vertical direction and that the fourth coil 714 is adjacent the third coil 712 in the vertical direction.

As used herein, the term adjacent may mean that two devices (e.g., coils) are close to one another on a given layer (e.g., as seen in the top view of FIG. 7). In addition, when two devices (e.g., coils) are on different layers, the term adjacent means that the two devices overlap with each other at least partially (e.g., one device is at least partially below or above the other device as seen in the view A-A of FIG. 7).

The second node n2 is coupled to an output pad 720 via a signal trace 722. Thus, as in FIG. 6, a signal from a transmitter (not shown in FIG. 7) flows from the first node n1 through the distributed T-coils 700, out the second node n2, and to the output pad 720 (e.g., for transmission to an off-chip component). In some examples, the distance between the distributed T-coils 700 (e.g., the second node n2) and the output pad 720 is less than 4 micrometers.

The third node n3 of FIG. 7 corresponds to the third node n3 of FIG. 6. Thus, the third node n3 may be coupled to an ESD circuit or some other type of circuitry (not shown in FIG. 7) in some examples.

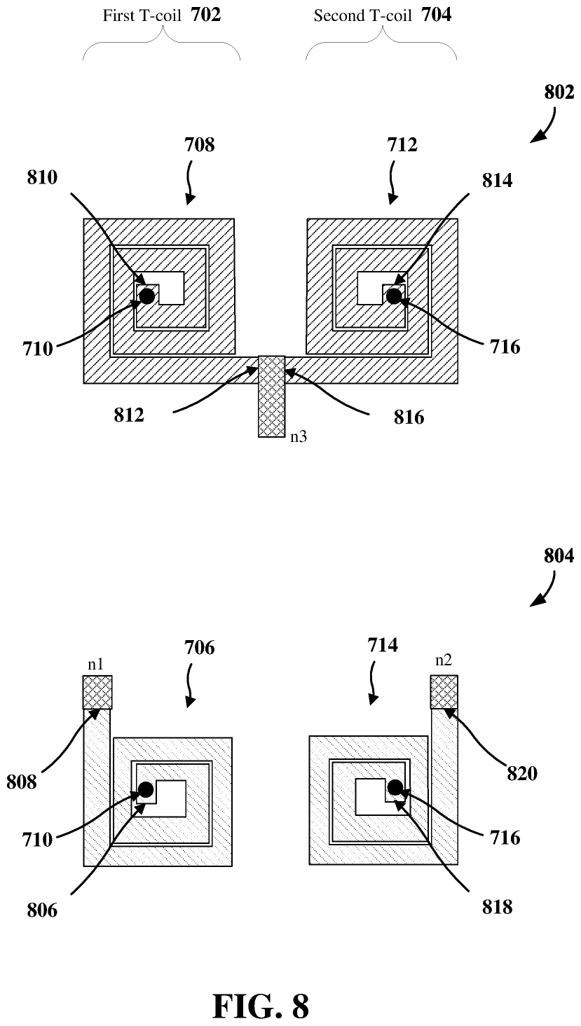

FIG. 8 illustrates the layers of the layout of FIG. 7 to provide more clarity. A first diagram 802 corresponds to the first layer L1 of FIG. 7. A second diagram 804 corresponds to the second layer L2 of FIG. 7.

As shown in the first diagram 802, the first layer L1 includes the second coil 708 and the third coil 712. Similarly, as shown in the second diagram 804, the second layer L2 includes the first coil 706 and the fourth coil 714.

The first coil 706 includes a first end 806 and a second end 808. The first end 806 is coupled to the first inter-layer interconnect 710. The second end 808 is coupled to the first node n1.

The second coil 708 includes a third end 810 and a fourth end 812. The third end 810 is coupled to the first inter-layer interconnect 710. The fourth end 812 is coupled to the third node n3 (e.g., a terminal).

The third coil 712 includes a fifth end 814 and a sixth end 816. The fifth end 814 is coupled to the second inter-layer interconnect 716. The sixth end 816 is coupled to the third node n3.

The fourth coil 714 includes a seventh end 818 and an eighth end 820. The seventh end 818 is coupled to the second inter-layer interconnect 716. The eighth end 820 is coupled to the second node n2.

The coils of FIG. 8 may be referred to as spiral coils. That is, the traces of each coil spiral inwards from an outer end to an inner end. In other words, each coil may be referred to as having a decreasing radius.

For example, the first coil 706 (first spiral coil) may be referred to as spiraling inward from the second end 808 to the first end 806 in a first direction (e.g., a counter-clockwise direction). The second coil 708 (second spiral coil) may be referred to as spiraling inward from the fourth end 812 to the third end 810 in a second direction (e.g., a clockwise direction). The third coil 712 (third spiral coil) may be referred to as spiraling inward from the sixth end 816 to the fifth end 814 in the first direction (e.g., a counter-clockwise direction). The fourth coil 714 (fourth spiral coil) may be referred to as spiraling inward from the eighth end 820 to the seventh end 818 in the second direction (e.g., a clockwise direction).

As used herein, the terms spiral and radius do not necessarily imply that that the coils have curved features. As shown in FIG. 8, a spiral coil may include a series of segments, where each segments is straight, not curved.

The coils of FIG. 8 may take other forms in other examples. For example, in some implementations, curved coils, hexagonal coils, triangular coils, or other shaped coils may be used as the spiral coils of the T-coils.

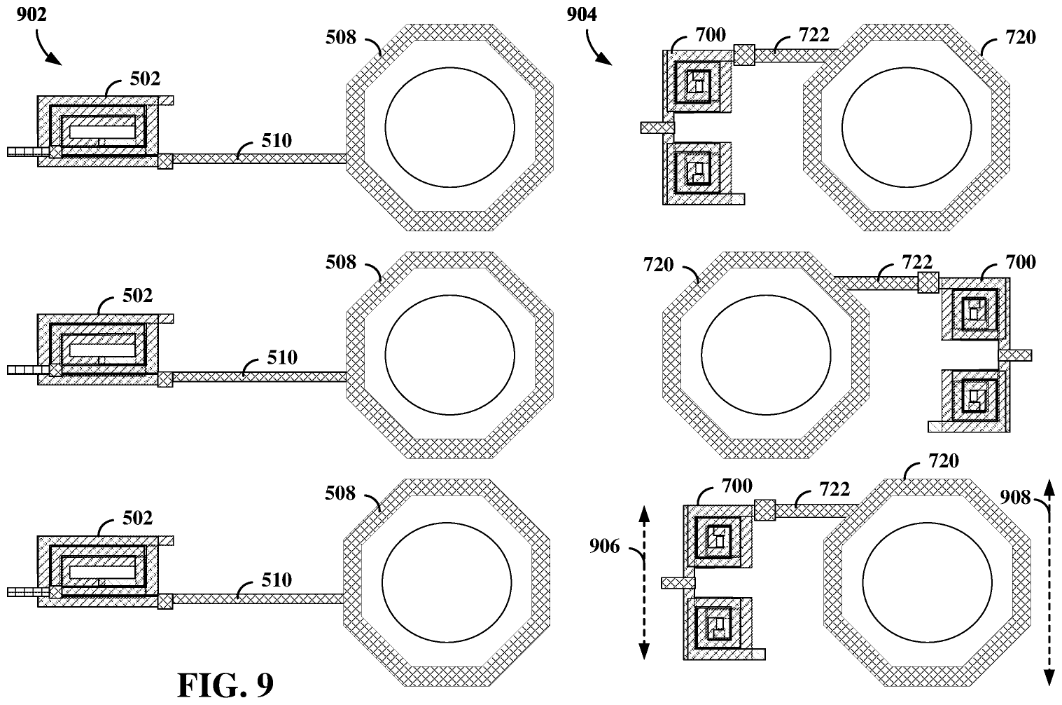

FIG. 9 contrasts the layout of FIG. 7 with the layout of FIG. 5 for a multi-lane scenario (e.g., employing single-ended signals or differential signals) in accordance with certain aspects of the disclosure. A first diagram 902 shows the layout of FIG. 5 with T-coils 502 and output pads 508. A second diagram 904 shows the layout of FIG. 7 with distributed T-coils 700 and output pads 720.

As illustrated, the design shown in the second diagram 904 provides significant savings in silicon area as compared to the design shown in the first diagram 902. For example, the width of the T-coil circuit and bump combination in the second diagram 904 is significantly less than the width of the T-coil circuit and pad combination in the first diagram 902. Consequently, the T-coil circuit and pad combination in the second diagram 904 may take up less space on an IC die. This frees up IC die area that may be used, for example, to provide additional functionality that might not otherwise be provided on the IC die.

In addition, in some examples, a distributed T-coil 700 and a pad 720 (e.g., bump) may be co-designed as a single element. For example, each of the three T-coil and pad combinations of the second diagram 904 may correspond to a single element. This enables these elements to be placed closer together for more efficient routing.

As shown in the second diagram 904, in some examples, the distributed T-coil 700 may be designed with a size that is comparable to the size of an output pad 720. For example, the height (and/or width) 906 of a distributed T-coil 700 may be slightly less than a height 908 of an output pad 720. This may provide a more efficient layout since the T-coil circuit and bump combination may take up substantially all of the space of the corresponding clement. Thus, there is very little wasted space within the element, again freeing up IC die area that may be used to provide other functionality. In some examples, the height and/or the width of a distributed T-coil 700 may be less than 35 micrometers.

In addition, the design shown in the second diagram 904 uses a significantly shorter signal trace 722 as compared to the signal trace 510 in the design shown in the first diagram 902. Thus, the design shown in the second diagram 904 can provide better signal characteristics (e.g., due to lower parasitic capacitance associated with a shorter signal trace). As discussed above, parasitic capacitance reduces the maximum data rate than an I/O circuit can achieve. Thus, by using the design shown in the second diagram 904, higher data rates can be achieved (e.g., as compared to the data rates that can be achieved using the design shown in the first diagram 902).

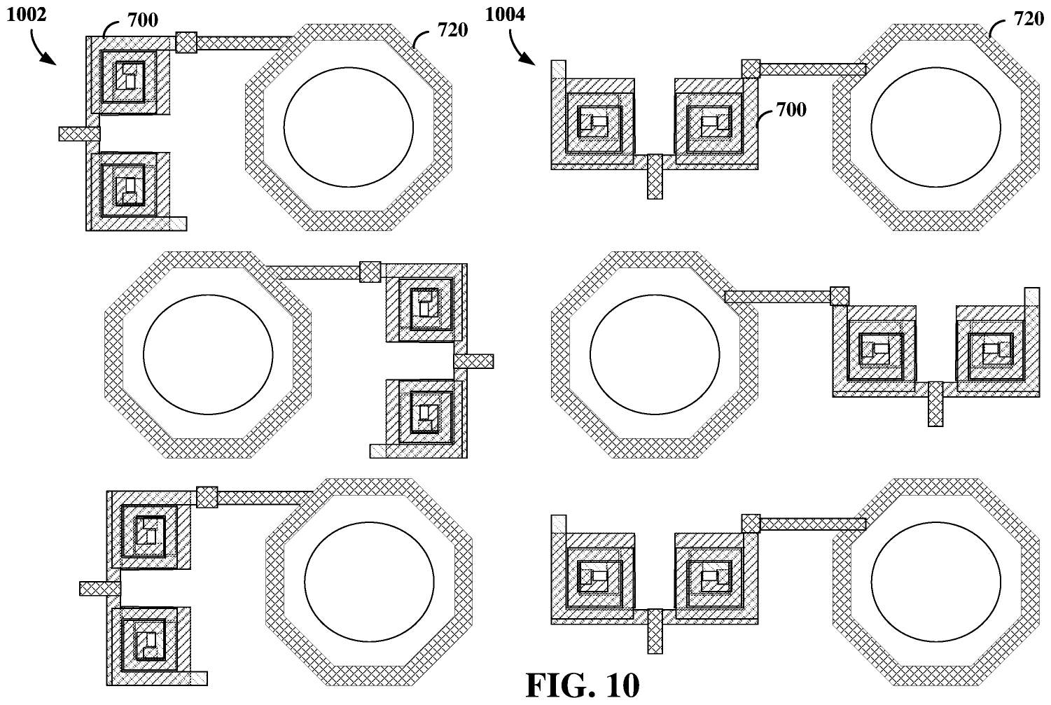

Moreover, the design shown in the second diagram 904 provides an improved floorplan (e.g., staggered bumps) that can provide better isolation and better matching between lanes in a multi-lane scenario. FIG. 10 illustrates two different layouts for such multi-lane scenarios.

FIG. 10 illustrates example layouts of the T-coil circuit of FIG. 6 or FIG. 9 for multi-lane scenarios in accordance with certain aspects of the disclosure. A first diagram 1002 illustrates the layout shown in the second diagram 904 of FIG. 9. In this example, each T-coil pair is arranged in a vertical orientation. As discussed above, this can provide a relatively narrow width for the T-coil circuit and bump combination which enables a relatively tight placement of the T-coil circuit and bump combinations. Consequently, each lane of a multi-lane bus may have similar lengths and/or routing. Thus, the characteristics (e.g., signal delay and parasitic capacitance) of each lane may be very similar (e.g., highly matched). This may facilitate a nearly identical arrival time for signals on each path at a receiver which, in turn, can enable higher data rates (e.g., since the receiver need not accommodate a wide range of signal reception times on a single bus).

A second diagram 1004 of FIG. 10 illustrates that the orientation of the distributed T-coil 700 may be changed to provide a compact layout for a staggered bump scenario. In this example, each T-coil pair is arranged in a horizontal orientation. As shown in the second diagram 1004, this can provide more separation between the pads. Since signal isolation increases with the distance between the signal paths, the design shown in the second diagram 1004 may provide better isolation (e.g., less cross-talk, interference, etc.) between the signals carried by the corresponding signal paths.

A multiple T-coil design as taught herein may be implemented in different ways in different examples. For example, a multiple T-coil design may be used with (or implemented in) a transmitter or a receiver. FIG. 6 discussed above is one example of a multiple T-coil design used with a transmitter.

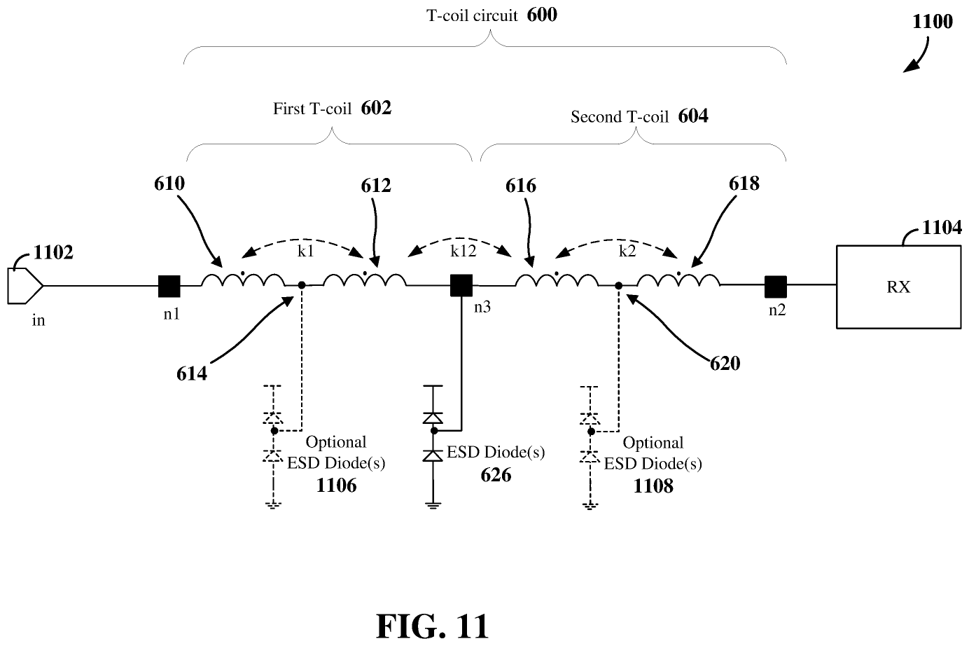

FIG. 11 illustrates an example of a T-coil circuit that includes two T-coils used with a receiver in accordance with certain aspects of the disclosure. In this case, a signal received via an input pad (bump) is routed through the T-coil circuit 600 to an input of a receiver 1104. It should be noted that any of the layouts discussed above (e.g., the layouts of FIG. 7, FIG. 8, the second diagram 904 of FIG. 9, the vertical orientation of the first diagram 1002 of FIG. 10, and the horizontal orientation of the second diagram 1004 of FIG. 10) may be applicable to the circuit of FIG. 11.

FIG. 11 also illustrates that in some examples, an electronic circuit may be coupled to the middle node of one or more of the T-coils. For example, one or more diodes (e.g., ESD diodes 1106) may be coupled to the first intermediate node. Alternatively, or in addition, one or more diodes (e.g., ESD diodes 1108) may be coupled to the second intermediate node. Other electronic circuits (e.g., including one or more of a capacitor, a resistor, an inductors, etc.) may be used in other examples.

In some examples, one or more of the attributes of the coils may be different in different implementations. For example, the impedance of one T-coil may be different from the impedance of another T-coil. As another example, the size of one T-coil may be different from the size of another T-coil. As a further example, the shape of one T-coil may be different from the shape of another T-coil. Also, the mutual inductance of one T-coil may be different from the mutual inductance of another T-coil. In addition, the layers used (e.g., the number of layers, the particular layers, etc.) for one T-coil may be different from the layers used for another T-coil.

In some examples, the nodes (terminals) of a multiple T-coil design may be implemented in different ways in different examples. For example, the nodes n1, n2, and n3 may extend from different areas of the T-coils in contrast with the upper left (node n1), upper right (node n2), and bottom center (node n3) design of FIG. 7.

Also, different labels may be used for the coils in different examples. For example, in FIG. 8, the coil 708 may be referred to as a first spiral coil, the coil 712 may be referred to as a second spiral coil, the coil 706 may be referred to as a third spiral coil, and the coil 714 may be referred to as a fourth spiral coil. In this case, the first spiral coil may be referred to as spiraling inward in a first direction (e.g., a clockwise direction), the second spiral coil may be referred to as spiraling inward in a second direction (e.g., a counter-clockwise direction), the third spiral coil may be referred to as spiraling inward in the second direction (e.g., a counter-clockwise direction), and the fourth spiral coil may be referred to as spiraling inward in the first direction (e.g., a clockwise direction).

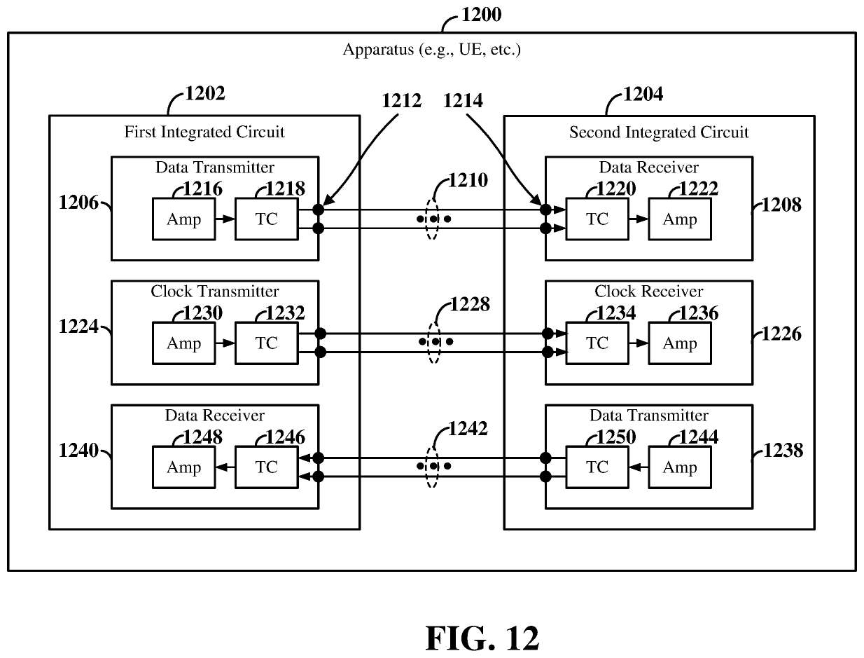

A multiple T-coil design as taught herein may be implemented in various types of circuits. For example, FIG. 12 illustrates that a multiple T-coil design may be incorporated into any suitable type of apparatus 1200 that employs one or more signal paths (e.g., for SerDes signaling, DDR signaling, radio frequency signaling, etc.). Such an apparatus may be a user equipment, a base station, a mobile device, a cellular (cell) phone, a smart phone, a session initiation protocol (SIP) phone, a laptop, a personal computer (PC), a notebook, a netbook, a smartbook, a tablet, a personal digital assistant (PDA), and a broad array of embedded systems, e.g., corresponding to an Internet of Things (IoT). A mobile apparatus may be, for example, an automotive or other transportation vehicle, a remote sensor or actuator, a robot or robotics device, a satellite radio, a global positioning system (GPS) device, an object tracking device, a drone, a multi-copter, a quad-copter, a remote control device, a consumer and/or wearable device, such as eyewear, a wearable camera, a virtual reality device, a smart watch, a health or fitness tracker, a digital audio player (e.g., MP3 player), a camera, a game console, etc. A mobile apparatus may be a digital home or smart home device such as a home audio, video, and/or multimedia device, an appliance, a vending machine, intelligent lighting, a home security system, a smart meter, etc. A mobile apparatus may be a smart energy device, a security device, a solar panel or solar array, a municipal infrastructure device controlling electric power (e.g., a smart grid), lighting, water, etc., an industrial automation and enterprise device, a logistics controller, agricultural equipment, etc. Still further, a mobile apparatus may provide for connected medicine or telemedicine support, i.e., health care at a distance. Telehealth devices may include telehealth monitoring devices and telehealth administration devices, the communicated information of which may be given preferential treatment or prioritized access over other types of information, e.g., in terms of prioritized access for transport of critical service data, and/or relevant quality of service (QOS) for transport of critical service data. A base station may be, for example, a network element in a radio access network responsible for radio transmission and reception in one or more service sets. In different technologies, standards, or contexts, an access point may variously be referred to by those skilled in the art as a base station, a base transceiver station (BTS), a radio base station, a radio transceiver, a transceiver function, a basic service set (BSS), an extended service set (ESS), a Node B (NB), an eNode B (eNB), a gNode B (gNB), a transmission and reception point (TRP), or some other suitable terminology.

In FIG. 12, an apparatus 1200 includes a first IC 1202 and a second IC 1204. The apparatus may include other ICs and components (not shown) as well.

The first IC 1202 includes a first data transmitter 1206 for sending data to a first data receiver 1208 of the second IC 1204 via a set of signal paths 1210. As shown in FIG. 12, each signal path may include a first bump 1212 at the first IC 1202 and a second bump 1214 at the second IC 1204.

As discussed herein, the first data transmitter 1206 and/or the first data receiver 1208 may use multiple T-coils to improve performance and/or provide a better IC layout. For example, a signal output by a first amplifier 1216 (e.g., a driver as discussed herein) is passed though a first T-coil circuit 1218 (e.g., corresponding to the T-coil circuit 600 of FIG. 6) and output at the first bump 1212. The signal passes through a signal path of the set of signal paths 1210 to the second bump 1214 to a second T-coil circuit 1220 (e.g., corresponding to the T-coil circuit 600 of FIG. 6) at the first data receiver 1208. The output of the T-coil circuit 1220 is provided to an input of a second amplifier 1222 (e.g., a receiver as discussed above).

The first IC 1202 also includes a clock transmitter 1224 for sending clock signals to a clock receiver 1226 of the second IC 1204 via a set of signal paths 1228. The clock transmitter 1224 and/or the clock receiver 1226 may use multiple T-coils to improve performance and/or provide a better IC layout. Accordingly, the clock transmitter 1224 may include a third amplifier 1230 and a third T-coil circuit 1232, and the clock receiver 1226 may include a fourth T-coil circuit 1234 and a fourth amplifier 1236 similar to the above.

The second IC 1204 also includes a second data transmitter 1238 for sending data signals to a second data receiver 1240 of the first IC 1202 via a set of signal paths 1242. The second data transmitter 1238 and/or the second data receiver 1240 may use multiple T-coils to improve performance and/or provide a better IC layout. Accordingly, the second data transmitter 1238 may include a fifth amplifier 1244 and a fifth T-coil circuit 1246, and the second data receiver 1240 may include a sixth T-coil circuit 1250 and a sixth amplifier 1248 similar to the above.

In some implementations, the signals paths between the components of FIG. 12 may be wireless paths (e.g., using radio frequency (RF) signals). For example, a signal output of an IC (e.g., the output of a T-coil circuit) may pass to an RF transmit chain. Similarly, the input to an IC may come from an RF receive chain.

The following provides an overview of various aspects of the present disclosure.

Aspect 1: An apparatus, comprising: a first spiral coil on a first layer, the first spiral coil comprising a first end and a second end, the first end being coupled to a first interconnect, the second end being coupled to a first terminal, the first spiral coil spiraling inward from the second end to the first end in a first direction; a second spiral coil adjacent to the first spiral coil on the first layer, the second spiral coil comprising a third end and a fourth end, the third end being coupled to a second interconnect, the fourth end being coupled to the first terminal, the second spiral coil spiraling inward from the fourth end to the third end in a second direction different from the first direction; a third spiral coil on a second layer that is parallel to the first layer, the third spiral coil comprising a fifth end and a sixth end, the fifth end being coupled to the first interconnect, the sixth end being coupled to a second terminal, the third spiral coil being arranged adjacent the first spiral coil; and a fourth spiral coil adjacent to the third spiral coil on the second layer, the fourth spiral coil comprising a seventh end and an eighth end, the seventh end being coupled to the second interconnect, the eighth end being coupled to a third terminal, the fourth spiral coil being arranged adjacent the second spiral coil.

Aspect 2: The apparatus of aspect 1, wherein the second terminal or the third terminal is coupled to a metal pad for a solder bump.

Aspect 3: The apparatus of aspect 2, wherein the second terminal and the metal pad or the third terminal and the metal pad comprise a single integrated circuit layout element.

Aspect 4: The apparatus of any of aspects 2 through 3, wherein: the first spiral coil has a first width; the second spiral coil has a second width; the metal pad has a third width; and a sum of the first width and the second width is less than the third width.

Aspect 5: The apparatus of any of aspects 2 through 4, wherein a distance between the metal pad and either the second terminal or the third terminal is less than 4 micrometers.

Aspect 6: The apparatus of any of aspects 1 through 5, wherein: the first spiral coil and the third spiral coil comprises a first T-coil of a T-coil structure; and the second spiral coil and the fourth spiral coil comprise a second T-coil of the T-coil structure.

Aspect 7: The apparatus of aspect 6, wherein a mutual coupling between the first T-coil and the second T-coil is less than 0.6.

Aspect 8: The apparatus of any of aspects 6 through 7, wherein: the second terminal and the third terminal are arranged on opposite ends of the T-coil structure along a first side of the T-coil structure; and the first terminal is arranged between the first T-coil and the second T-coil on a second side of the T-coil structure, opposite the first side of the T-coil structure.

Aspect 9: The apparatus of any of aspects 1 through 8, wherein: the first direction is a clockwise direction; and the second direction is a counter-clockwise direction.

Aspect 10: The apparatus of any of aspects 1 through 9, wherein: the third spiral coil spirals inward from the sixth end to the fifth end in the second direction; and the fourth spiral coil spirals inward from the eighth end to the seventh end in the first direction.

Aspect 11: The apparatus of any of aspects 1 through 10, wherein each of the first spiral coil, the second spiral coil, the third spiral coil, and the fourth spiral coil has a rectangular shape.

Aspect 12: The apparatus of any of aspects 1 through 11, wherein each of the first spiral coil, the second spiral coil, the third spiral coil, and the fourth spiral coil has a width of less than 35 micrometers.

Aspect 13: The apparatus of aspect 12, wherein the second terminal or the third terminal is coupled to an input pad or an output pad.

Aspect 14: The apparatus of any of aspects 1 through 13, further comprising: at least one electrical component coupled to the first terminal.

Aspect 15: The apparatus of aspect 14, wherein the at least one electrical component comprises at least one diode.

Aspect 16: The apparatus of any of aspects 1 through 15, further comprising: at least one first electrical component coupled to the first interconnect; and at least one second electrical component coupled to the second interconnect.

Aspect 17: The apparatus of aspect 16, wherein: the at least one first electrical component comprises a first diode; and the at least one second electrical component comprises a second diode.

Aspect 18: The apparatus of any of aspects 1 through 17, wherein: the first spiral coil has a first width; and the second spiral coil has a second width that is different from the first width.

Aspect 19: The apparatus of any of aspects 1 through 18, wherein: the first spiral coil is associated with a first inductance value; and the second spiral coil is associated with a second inductance value that is different from the first inductance value.

Aspect 20: The apparatus of any of aspects 1 through 19, wherein: the first spiral coil has a first shape; and the second spiral coil has a second shape that is different from the first shape.

Aspect 21: The apparatus of any of aspects 1 through 20, wherein: the third spiral coil spirals inward from the sixth end to the fifth end in the second direction; the fourth spiral coil spirals inward from the eighth end to the seventh end in the first direction; the first direction is a clockwise direction; the second direction is a counter-clockwise direction; each of the first spiral coil, the second spiral coil, the third spiral coil, and the fourth spiral coil has a rectangular shape; and the second terminal or the third terminal is coupled to an input pad or an output pad.

Aspect 22: The apparatus of any of aspects 1 through 21, wherein the first spiral coil, the second spiral coil, the third spiral coil, and the fourth spiral coil comprise a first T-coil structure.

Aspect 23: The apparatus of aspect 22, further comprising: a first metal pad for a first solder bump coupled to the first T-coil structure; and a second metal pad for a second solder bump coupled to a second T-coil structure, the first metal pad being arranged adjacent the second T-coil structure, and the second metal pad being arranged adjacent the first T-coil structure.

Aspect 24: The apparatus of aspect 23, wherein: the first metal pad and the first T-coil structure comprise a first structure; the second metal pad and the second T-coil structure comprise a second structure; the first metal pad is offset in a third direction relative to an axis bisecting each of the first structure and the second structure; and the second metal pad is offset in a fourth direction relative to the axis, the fourth direction being opposite the third direction.

Aspect 25: The apparatus of any of aspects 1 through 24, wherein the apparatus is configured as a receiver, the apparatus further comprising: a receiver input pad coupled to the second terminal; and an amplifier comprising an input terminal, the input terminal being coupled to the third terminal.

Aspect 26: The apparatus of any of aspects 1 through 24, wherein the apparatus is configured as a transmitter, the apparatus further comprising: an amplifier comprising an output terminal, the output terminal being coupled to the second terminal; and a transmitter output pad coupled to the third terminal.

Aspect 27: An integrated circuit, comprising: a first metal layer defining a first spiral coil, a second spiral coil, and a first terminal; a second metal layer defining a third spiral coil, a fourth spiral coil, a second terminal, and a third terminal; a first inter-layer interconnect between the first metal layer and the second metal layer; and a second inter-layer interconnect between the first metal layer and the second metal layer; a first end of the first spiral coil being coupled to the first inter-layer interconnect, a second end of the first spiral coil being coupled to the first terminal, the first spiral coil spiraling inward from the second end to the first end in a clockwise direction, a third end of the second spiral coil being coupled to the second inter-layer interconnect, a fourth end of the second spiral coil being coupled to the first terminal, the second spiral coil spiraling inward from the fourth end to the third end in a counter-clockwise direction, a fifth end of the third spiral coil being coupled to the first inter-layer interconnect, a sixth end of the third spiral coil being coupled to the second terminal, the third spiral coil being arranged adjacent the first spiral coil, and a seventh end of the fourth spiral coil being coupled to the second inter-layer interconnect, an eighth end of the fourth spiral coil being coupled to the third terminal, the fourth spiral coil being arranged adjacent the second spiral coil.

Aspect 28: The integrated circuit of aspect 27, wherein: the third spiral coil spirals inward from the sixth end to the fifth end in the counter-clockwise direction; and the fourth spiral coil spirals inward from the eighth end to the seventh end in the clockwise direction.

Aspect 29: The integrated circuit of any of aspects 27 through 28, wherein each of the first spiral coil, the second spiral coil, the third spiral coil, and the fourth spiral coil has a rectangular shape.

Aspect 30: The integrated circuit of any of aspects 27 through 29, further comprising: at least one diode coupled to the first terminal.

Aspect 31: The integrated circuit of any of aspects 27 through 30, further comprising: at least one first diode coupled to the first inter-layer interconnect; and at least one second diode coupled to the second inter-layer interconnect.

Aspect 32: The integrated circuit of any of aspects 27 through 31, wherein the second terminal is coupled to a metal pad for a solder bump.

Aspect 33: The integrated circuit of aspect 32, wherein the second terminal and the metal pad comprise a single integrated circuit layout element.

Aspect 34: The integrated circuit of any of aspects 27 through 35, wherein the third terminal is coupled to a metal pad for a solder bump.

Aspect 35: The integrated circuit of aspect 34, wherein the third terminal and the metal pad comprise a single integrated circuit layout element.

Aspect 36: The integrated circuit of any of aspects 27 through 35, wherein the first spiral coil, the second spiral coil, the third spiral coil, and the fourth spiral coil comprise a first T-coil structure.

Aspect 37: The integrated circuit of aspect 36, further comprising: a first metal pad for a first solder bump coupled to the first T-coil structure; and a second metal pad for a second solder bump coupled to a second T-coil structure, the first metal pad being arranged adjacent the second T-coil structure, and the second metal pad being arranged adjacent the first T-coil structure.

Aspect 38: The integrated circuit of aspect 37, wherein: the first metal pad and the first T-coil structure comprise a first structure; the second metal pad and the second T-coil structure comprise a second structure; the first metal pad is offset in a first direction relative to an axis bisecting each of the first structure and the second structure; and the second metal pad is offset in a second direction relative to the axis, the second direction being opposite the first direction.

Aspect 39: The integrated circuit of any of aspects 27 through 38, wherein the integrated circuit is configured as a receiver, the integrated circuit further comprising: a receiver input pad coupled to the second terminal; and an amplifier comprising an input terminal, the input terminal being coupled to the third terminal.

Aspect 40: The integrated circuit of any of aspects 27 through 38, wherein the integrated circuit is configured as a transmitter, the integrated circuit further comprising: an amplifier comprising an output terminal, the output terminal being coupled to the second terminal; and a transmitter output pad coupled to the third terminal.

Aspect 41: An apparatus, comprising: a first T-coil, the first T-coil comprising a first coil coupled to a second coil at a first node, the first T-coil further comprising a first electrical component coupled to the first node; a second T-coil, the second T-coil comprising a third coil coupled to a fourth coil at a second node, the second T-coil further comprising a second electrical component coupled to the second node, the second T-coil being coupled to the first T-coil at a third node; and a third electrical component coupled to the third node.

Aspect 42: The apparatus of aspect 41, wherein the first electrical component comprises a plurality of diodes.

Aspect 43: The apparatus of any of aspects 41 through 42, wherein: the second electrical component comprises a first diode; and the third electrical component comprises a second diode.

Aspect 44: The apparatus of any of aspects 41 through 43, wherein a mutual coupling between the first T-coil and the second T-coil is less than 0.6.

Aspect 45: The apparatus of any of aspects 41 through 44, wherein the apparatus is configured as a receiver, the apparatus further comprising: a receiver input pad coupled to the first coil; and an amplifier comprising an input terminal, the input terminal being coupled to the fourth coil.

Aspect 46: The apparatus of any of aspects 41 through 44, wherein the apparatus is configured as a transmitter, the apparatus further comprising: an amplifier comprising an output terminal, the output terminal being coupled to first coil; and a transmitter output pad coupled to the fourth coil.

Within the present disclosure, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another-even if they do not directly physically touch each other. For instance, a first object may be coupled to a second object even though the first object is never directly physically in contact with the second object. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure. As used herein, the term “determining” may include, for example, ascertaining, resolving, selecting, choosing, establishing, calculating, computing, processing, deriving, investigating, looking up (e.g., looking up in a table, a database or another data structure), and the like. Also, “determining” may include receiving (e.g., receiving information), accessing (e.g., accessing data in a memory), and the like.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b, and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. An apparatus, comprising:
a first spiral coil on a first layer, the first spiral coil comprising a first end and a second end, the first end being coupled to a first interconnect, the second end being coupled to a first terminal, the first spiral coil spiraling inward from the second end to the first end in a first direction;
a second spiral coil adjacent to the first spiral coil on the first layer, the second spiral coil comprising a third end and a fourth end, the third end being coupled to a second interconnect, the fourth end being coupled to the first terminal, the second spiral coil spiraling inward from the fourth end to the third end in a second direction different from the first direction;
a third spiral coil on a second layer that is parallel to the first layer, the third spiral coil comprising a fifth end and a sixth end, the fifth end being coupled to the first interconnect, the sixth end being coupled to a second terminal, the third spiral coil being arranged adjacent the first spiral coil; and
a fourth spiral coil adjacent to the third spiral coil on the second layer, the fourth spiral coil comprising a seventh end and an eighth end, the seventh end being coupled to the second interconnect, the eighth end being coupled to a third terminal, the fourth spiral coil being arranged adjacent the second spiral coil.

2. The apparatus of claim 1, wherein the second terminal or the third terminal is coupled to a metal pad for a solder bump.

3. The apparatus of claim 2, wherein the second terminal and the metal pad or the third terminal and the metal pad comprise a single integrated circuit layout element.

4. The apparatus of claim 2, wherein:
the first spiral coil has a first width;
the second spiral coil has a second width;
the metal pad has a third width; and
a sum of the first width and the second width is less than the third width.

5. The apparatus of claim 2, wherein a distance between the metal pad and either the second terminal or the third terminal is less than 4 micrometers.

6. The apparatus of claim 1, wherein:
the first spiral coil and the third spiral coil comprises a first T-coil of a T-coil structure; and
the second spiral coil and the fourth spiral coil comprise a second T-coil of the T-coil structure.

7. The apparatus of claim 6, wherein a mutual coupling between the first T-coil and the second T-coil is less than 0.6.

8. The apparatus of claim 6, wherein:
the second terminal and the third terminal are arranged on opposite ends of the T-coil structure along a first side of the T-coil structure; and
the first terminal is arranged between the first T-coil and the second T-coil on a second side of the T-coil structure, opposite the first side of the T-coil structure.

9. The apparatus of claim 1, wherein:
the first direction is a clockwise direction; and
the second direction is a counter-clockwise direction.

10. The apparatus of claim 1, wherein:
the third spiral coil spirals inward from the sixth end to the fifth end in the second direction; and
the fourth spiral coil spirals inward from the eighth end to the seventh end in the first direction.

11. The apparatus of claim 1, wherein each of the first spiral coil, the second spiral coil, the third spiral coil, and the fourth spiral coil has a rectangular shape.

12. The apparatus of claim 1, wherein each of the first spiral coil, the second spiral coil, the third spiral coil, and the fourth spiral coil has a width of less than 35 micrometers.

13. The apparatus of claim 1, wherein the second terminal or the third terminal is coupled to an input pad or an output pad.

14. The apparatus of claim 1, further comprising:
at least one electrical component coupled to the first terminal.

15. The apparatus of claim 14, wherein the at least one electrical component comprises at least one diode.

16. The apparatus of claim 1, further comprising:
at least one first electrical component coupled to the first interconnect; and
at least one second electrical component coupled to the second interconnect.

17. The apparatus of claim 16, wherein:
the at least one first electrical component comprises a first diode; and
the at least one second electrical component comprises a second diode.

18. The apparatus of claim 1, wherein:
the first spiral coil has a first width; and
the second spiral coil has a second width that is different from the first width.

19. The apparatus of claim 1, wherein:
the first spiral coil is associated with a first inductance value; and
the second spiral coil is associated with a second inductance value that is different from the first inductance value.

20. The apparatus of claim 1, wherein:
the first spiral coil has a first shape; and
the second spiral coil has a second shape that is different from the first shape.

21. The apparatus of claim 1, wherein:
the third spiral coil spirals inward from the sixth end to the fifth end in the second direction;
the fourth spiral coil spirals inward from the eighth end to the seventh end in the first direction;
the first direction is a clockwise direction;
the second direction is a counter-clockwise direction;
each of the first spiral coil, the second spiral coil, the third spiral coil, and the fourth spiral coil has a rectangular shape; and
the second terminal or the third terminal is coupled to an input pad or an output pad.

22. The apparatus of claim 1, wherein the first spiral coil, the second spiral coil, the third spiral coil, and the fourth spiral coil comprise a first T-coil structure.

23. The apparatus of claim 22, further comprising:
a first metal pad for a first solder bump coupled to the first T-coil structure; and
a second metal pad for a second solder bump coupled to a second T-coil structure, the first metal pad being arranged adjacent the second T-coil structure, and the second metal pad being arranged adjacent the first T-coil structure.

24. The apparatus of claim 23, wherein:
the first metal pad and the first T-coil structure comprise a first structure;
the second metal pad and the second T-coil structure comprise a second structure;
the first metal pad is offset in a third direction relative to an axis bisecting each of the first structure and the second structure; and
the second metal pad is offset in a fourth direction relative to the axis, the fourth direction being opposite the third direction.

25. The apparatus of claim 1, wherein the apparatus is configured as a receiver, the apparatus further comprising:
a receiver input pad coupled to the second terminal; and
an amplifier comprising an input terminal, the input terminal being coupled to the third terminal.

26. The apparatus of claim 1, wherein the apparatus is configured as a transmitter, the apparatus further comprising:
an amplifier comprising an output terminal, the output terminal being coupled to the second terminal; and
a transmitter output pad coupled to the third terminal.

27. An integrated circuit, comprising:
a first metal layer defining a first spiral coil, a second spiral coil, and a first terminal;
a second metal layer defining a third spiral coil, a fourth spiral coil, a second terminal, and a third terminal;
a first inter-layer interconnect between the first metal layer and the second metal layer; and
a second inter-layer interconnect between the first metal layer and the second metal layer;
a first end of the first spiral coil being coupled to the first inter-layer interconnect, a second end of the first spiral coil being coupled to the first terminal, the first spiral coil spiraling inward from the second end to the first end in a clockwise direction,
a third end of the second spiral coil being coupled to the second inter-layer interconnect, a fourth end of the second spiral coil being coupled to the first terminal, the second spiral coil spiraling inward from the fourth end to the third end in a counter-clockwise direction,
a fifth end of the third spiral coil being coupled to the first inter-layer interconnect, a sixth end of the third spiral coil being coupled to the second terminal, the third spiral coil being arranged adjacent the first spiral coil, and
a seventh end of the fourth spiral coil being coupled to the second inter-layer interconnect, an eighth end of the fourth spiral coil being coupled to the third terminal, the fourth spiral coil being arranged adjacent the second spiral coil.

28. The integrated circuit of claim 27, wherein:
the third spiral coil spirals inward from the sixth end to the fifth end in the counter-clockwise direction; and
the fourth spiral coil spirals inward from the eighth end to the seventh end in the clockwise direction.

29. The integrated circuit of claim 27, wherein each of the first spiral coil, the second spiral coil, the third spiral coil, and the fourth spiral coil has a rectangular shape.

30. The integrated circuit of claim 27, further comprising:
at least one diode coupled to the first terminal.

31. The integrated circuit of claim 27, further comprising:
at least one first diode coupled to the first inter-layer interconnect; and
at least one second diode coupled to the second inter-layer interconnect.

32. The integrated circuit of claim 27, wherein the second terminal is coupled to a metal pad for a solder bump.

33. The integrated circuit of claim 32, wherein the second terminal and the metal pad comprise a single integrated circuit layout element.

34. The integrated circuit of claim 27, wherein the third terminal is coupled to a metal pad for a solder bump.

35. The integrated circuit of claim 34, wherein the third terminal and the metal pad comprise a single integrated circuit layout element.

36. The integrated circuit of claim 27, wherein the first spiral coil, the second spiral coil, the third spiral coil, and the fourth spiral coil comprise a first T-coil structure.

37. The integrated circuit of claim 36, further comprising:
a first metal pad for a first solder bump coupled to the first T-coil structure; and
a second metal pad for a second solder bump coupled to a second T-coil structure, the first metal pad being arranged adjacent the second T-coil structure, and the second metal pad being arranged adjacent the first T-coil structure.

38. The integrated circuit of claim 37, wherein:
the first metal pad and the first T-coil structure comprise a first structure;
the second metal pad and the second T-coil structure comprise a second structure;
the first metal pad is offset in a first direction relative to an axis bisecting each of the first structure and the second structure; and
the second metal pad is offset in a second direction relative to the axis, the second direction being opposite the first direction.

39. The integrated circuit of claim 27, wherein the integrated circuit is configured as a receiver, the integrated circuit further comprising:
a receiver input pad coupled to the second terminal; and
an amplifier comprising an input terminal, the input terminal being coupled to the third terminal.

40. The integrated circuit of claim 27, wherein the integrated circuit is configured as a transmitter, the integrated circuit further comprising:
an amplifier comprising an output terminal, the output terminal being coupled to the second terminal; and
a transmitter output pad coupled to the third terminal.
